(19) United States
(12) Patent Application Publication
(10) Pub. No.: US 2012/0067623 A1
(43) Pub. Date: Mar. 22, 2012

(54) HEAT-RADIATING SUBSTRATE AND METHOD FOR MANUFACTURING THE SAME

(75) Inventors: Sung Keun PARK, Gyunggi-do (KR); Chang Hyun LIM, Seoul (KR); Seog Moon CHOI, Seoul (KR); Kwang Soo KIM, Gyunggi-do (KR); Jung Eun KANG, Gyunggi-do (KR)

(73) Assignee: SAMSUNG ELECTRO-MECHANICS CO., LTD., Gyunggi-do (KR)

(21) Appl. No.: 13/007,414

(22) Filed: Jan. 14, 2011

(30) Foreign Application Priority Data
Sep. 16, 2010 (KR) 10-2010-0091226

(51) Int. Cl. H05K 1/00; H05K 3/02

(52) U.S. Cl. 174/252; 29/846

(57) ABSTRACT

Disclosed herein is a heat-radiating substrate, including: a copper substrate; an alumina layer formed on one side of the copper substrate; a first circuit layer formed on the alumina layer; and a second circuit layer formed on the first circuit layer, wherein a heat-radiating element is mounted on a first pad of the first circuit layer or a second pad of the second circuit layer, or is directly mounted on the exposed side of the copper substrate after forming an opening on the alumina layer.

### CROSS REFERENCE TO RELATED ED APPLICATION

This application claims the benefit of Korean Patent Application No. 10-2010-0091226, filed Sep. 16, 2010, entitled “Heat-radiating substrate and method for manufacturing the same”, which is hereby incorporated by reference in its entirety into this application.

### BACKGROUND OF THE INVENTION

1. Technical Field

The present invention relates to a heat-radiating substrate and a method of manufacturing the same.

2. Description of the Related Art

Recently, in order to solve the problems with the heat radiation of power elements and power modules applied in various fields, efforts have been made to manufacture various types of heat-radiating substrates using metal materials having high thermal conductivity. Further, heat-radiating substrates which can maximize heat radiation rate using anodization have been researched.

FIGS. 1 to 3 are sectional views showing a conventional method of manufacturing a heat-radiating substrate using an anodizing process. Hereinafter, the conventional method of manufacturing a heat-radiating substrate will be described with reference to FIGS. 1 to 3.

First, an anodized substrate 111, which is formed by forming an alumina layer 120 on one side of an aluminum substrate using an anodizing process, is provided.

Subsequently, a circuit layer 130 is formed on one side of the anodized substrate 111 by electrolytic plating or electroless plating.

In a conventional anodized heat-radiating substrate, since aluminum exhibits an excellent heat transfer effect, the heat emitted from a heat-generating element is discharged to the outside by an aluminum substrate. Therefore, the heat-generating element mounted on the anodized heat-radiating substrate continuously emits high-temperature heat, thus solving the problem of the performance of the heat-generating element deteriorating.

However, as electronic components become small and thin, the density of heat-generating elements locally arranged on a heat-radiating substrate becomes high, and thus the heat-radiating substrate must rapidly send the heat emitted from the heat-generating elements to the outside.

In order to solve such a problem, a heat-radiating substrate may be fabricated using a material having excellent heat absorptivity and high heat radiation performance.

However, the raw material of a base plate, which can be used in a process of manufacturing a heat-radiating substrate using an anodizing process, is limited to aluminum or an aluminum alloy. Therefore, when a copper plate is used as the base plate, there is a problem in that it is impossible to form an alumina layer on the copper plate.

FIG. 4 is a sectional view showing a conventional heat-radiating substrate package 200 including a heat-generating element mounted thereon.

In the conventional heat-radiating substrate package 200, an epoxy resin layer 220 is formed on an aluminum or copper plate 210 as an insulation layer, and a circuit layer 230 is formed on the epoxy resin layer 220 using aluminum or copper. The circuit layer 230 is sequentially mounted on a pad 240 thereof with a heat diffuser 250 and a heat-generating element 260, and the heat-generating element 260 is connected to a circuit pattern of the circuit layer 230 using aluminum wires 270

However, since the thermal conductivity of the epoxy resin layer 220 which is generally used as an insulation layer is lower than that of an alumina layer, the heat radiation capacity of the conventional heat-radiating substrate package 200 is limited.

### SUMMARY OF THE INVENTION

Accordingly, the present invention has been devised to solve the above-mentioned problems, and the present invention intends to provide a heat-radiating substrate which can improve heat radiation characteristics by replacing an aluminum substrate with a copper substrate having high thermal conductivity using an anodizing process.

Further, the present invention intends to provide a heat-radiating substrate which can solve the problem of an insulation layer being separated at high temperature by using an alumina layer as an insulation layer instead of an epoxy resin layer.

Moreover, the present invention intends to provide a heat-radiating substrate which can improve heat radiation characteristics by removing a part of an alumina layer formed on a copper substrate to form an opening and then directly mounting a heat-generating element on the copper substrate exposed by the opening.

An aspect of the present invention provides a heat-radiating substrate, including: a copper substrate; an alumina layer formed on one side of the copper substrate; and a first circuit layer formed on the alumina layer and including a first circuit pattern and a first pad. The heat-radiating substrate may further include a seed layer formed between the copper substrate and the alumina layer.

Here, the first circuit layer may be made of copper or aluminum.

Further, the first pad may include a heat-generating element mounted thereon.

Further, an opening may be formed in the alumina layer, and a heat-generating element may be mounted on the copper substrate exposed by the opening.

Another aspect of the present invention provides a heat-radiating substrate, including: a copper substrate; an alumina layer formed on one side of the copper substrate; a first circuit layer formed on the alumina layer and including a first circuit pattern and a first pad; and a second circuit layer formed on the first circuit layer and including a second circuit pattern corresponding to the first circuit pattern and a second pad corresponding to the first pad. The heat-radiating substrate may further include a seed layer formed between the copper substrate and the alumina layer.

Here, the first circuit layer may be made of aluminum, and the second circuit layer may be made of copper.

Further, the second pad may include a heat-generating element mounted thereon.

Further, an opening may be formed in the alumina layer, and a heat-generating element may be mounted on the copper substrate exposed by the opening.

Another aspect of the present invention provides a method of manufacturing a heat-radiating substrate, including: providing an anodized substrate including an aluminum substrate and an alumina layer formed on both sides of the aluminum substrate; forming a copper substrate on one side of the anodized substrate; removing the anodized substrate except for a portion of the alumina layer of the anodized substrate which is in contact with the copper substrate; and forming a first circuit layer including a first circuit pattern and a first pad on the exposed surface of the alumina layer which is in contact with the copper substrate. The method may further include, between the providing of the anodized substrate and the forming of the copper substrate: forming a seed layer on one side of the anodized substrate.

Further, the method may further include, after the forming of the first circuit layer: forming an opening in the alumina layer; and mounting a heat-generating element on the copper substrate exposed by the opening.

Further, the method may further include, after the forming of the first circuit layer: mounting a heat-generating element on the first pad.

Further, the first circuit layer may be made of copper.

Still another aspect of the present invention provides a method of manufacturing a heat-radiating substrate, including: providing an anodized substrate including an aluminum substrate and an alumina layer formed on both sides of the aluminum substrate; forming a copper substrate on one side of the anodized substrate; removing the alumina layer formed on the side of the aluminum substrate on which the copper substrate was not formed and then partially removing the aluminum substrate to form a first circuit layer including a first circuit pattern and a first pad; and forming a second circuit layer including a second circuit pattern corresponding to the first circuit pattern of the first circuit layer and a second pad corresponding to the first pad of the first circuit layer. The method may further include, between the providing of the anodized substrate and the forming of the copper substrate: forming a seed layer on one side of the anodized substrate.

Further, the method may further include, after the forming of the second circuit layer: forming an opening in the alumina layer; and mounting a heat-generating element on the copper substrate exposed by the opening.

Further, the method may further include, after the forming of the second circuit layer: mounting a heat-generating element on the second pad.

Further, the second circuit layer may be made of copper.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 3 are sectional views showing a conventional method of manufacturing a heat-radiating substrate;

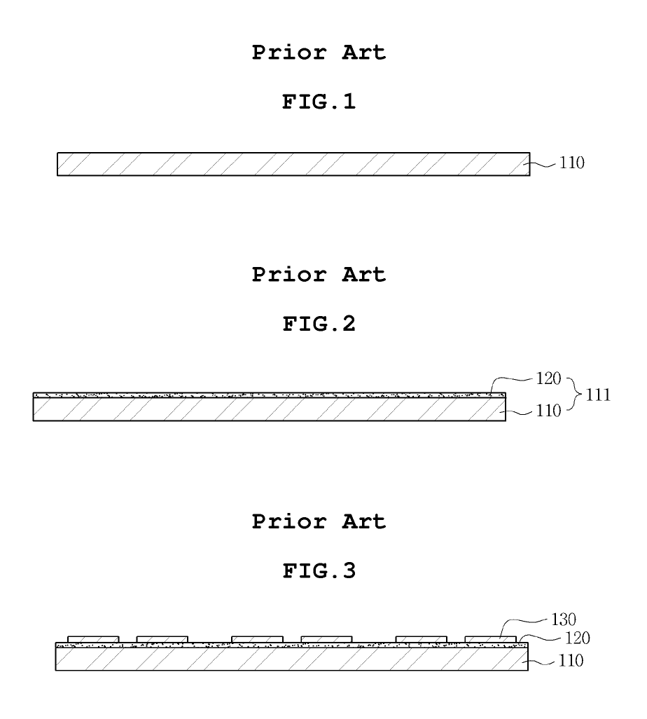

FIG. 4 is a sectional view showing a conventional heat-radiating substrate including a heat-generating element mounted thereon;

FIG. 5 is a sectional view showing a heat-radiating substrate according to a first embodiment of the present invention;

FIG. 6 is a sectional view showing a heat-radiating substrate according to a second embodiment of the present invention;

FIGS. 7 to 11 are sectional views showing a method of manufacturing a heat-radiating substrate according to a first embodiment of the present invention;

FIGS. 12 to 19 are sectional views showing a method of manufacturing a heat-radiating substrate according to a second embodiment of the present invention; and

FIGS. 20 and 21 are sectional views showing heat-radiating substrates each being mounted with a heat-generating element.

### DESCRIPTION OF THE PREFERRED EMBODIMENTS

The objects, features and advantages of the present invention will be more clearly understood from the following detailed description of preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Structure of a Heat-Radiating Substrate

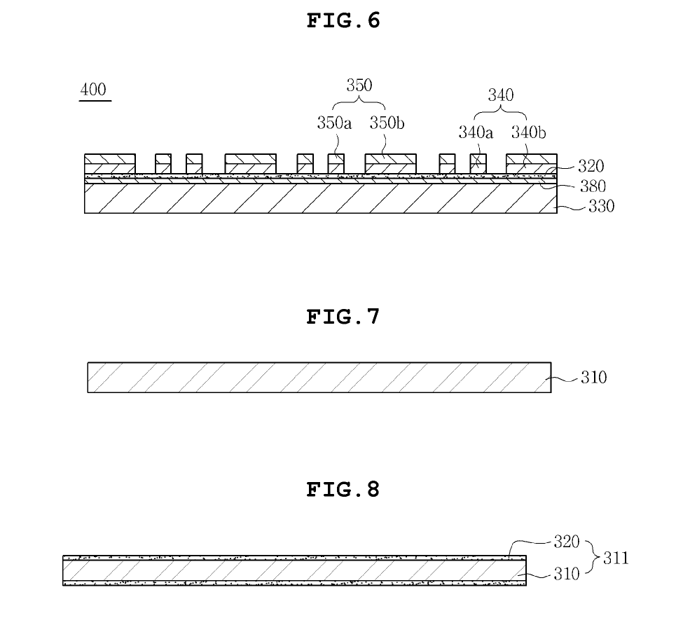

FIG. 5 is a sectional view showing a heat-radiating substrate according to a first embodiment of the present invention.

As shown in FIG. 5, the heat-radiating substrate 300 according to this embodiment includes a copper substrate 330, an alumina layer 320 formed on one side of the copper substrate 330, and a first circuit layer 340 formed on the alumina layer 320. Here, the first circuit layer 340 includes a first circuit pattern 340a and a first pad 340b. Further, the heat-radiating substrate 300 may further include a seed layer 380 formed between the copper substrate 330 and the alumina layer 320.

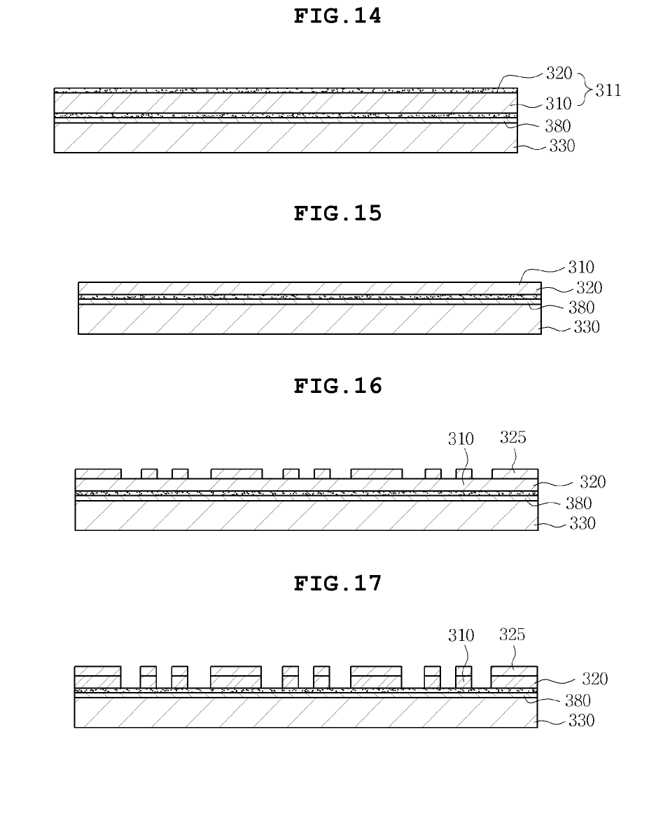

The copper substrate 330, which is a base member of the heat-radiating substrate 300, serves to discharge the heat emitted from a heat-generating element to the atmosphere. Since the copper substrate 330 has high strength compared to a resin substrate, it is highly resistant to the stress externally applied to the heat-radiating substrate 300. Further, in terms of thermal conductivity, aluminum has a thermal conductivity of 238 W/mK, whereas copper has a thermal conductivity of 397 W/mK. Therefore, when the copper substrate 330 is used as a base member of the heat-radiating substrate 300 instead of an aluminum substrate 310 (refer to FIGS. 7 to 10), it is possible to maximize the heat radiation effect of the heat-radiating substrate 300.

The alumina layer 320 is formed by anodizing an aluminum substrate 310 (refer to FIGS. 7 and 8). Here, the alumina layer 320, which is an insulation layer formed on the copper substrate 330, serves to prevent the electrical short of the first circuit layer 340 and the copper substrate 330. Further, since the alumina layer 320 is formed by an anodizing process, it is possible to realize a high-purity insulation layer.

Meanwhile, an epoxy resin, which is generally used to form an insulation layer, has a thermal conductivity of 2˜4 W/mK, whereas the alumina layer 320, which is formed by an anodizing process, has a thermal conductivity of 20˜25 W/mK. Therefore, when the alumina layer 320 having high thermal conductivity is used as an insulation layer, it is possible to further improve the heat radiation characteristics of the heat-radiating substrate 300.

Meanwhile, a description of a process of forming an alumina layer 320 on a copper substrate 330 will be contained in the following description of a method of manufacturing a heat-radiating substrate.

The first circuit layer 340 includes the first circuit pattern 340a and the first pad 340b, and is formed on the alumina layer 320. Further, the first circuit layer 340 may be made of aluminum or copper.

The seed layer 380, which is a thin metal layer formed on the alumina layer 320 by electroless plating or sputtering, serves as an incoming line when forming the copper substrate 330 on the alumina layer 320. However, the seed layer 380 may not be formed depending on the method of forming the copper substrate 330.

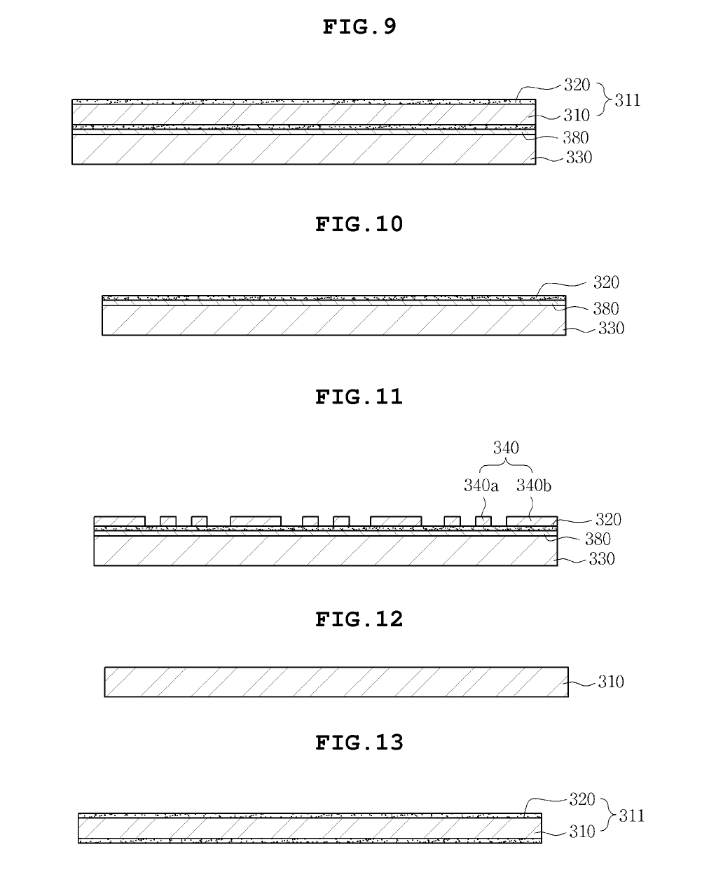

FIG. 6 is a sectional view showing a heat-radiating substrate according to a second embodiment of the present invention.

As shown in FIG. 6, the heat-radiating substrate 400 according to this embodiment includes a copper substrate 330, an alumina layer 320 formed on one side of the copper substrate 330, a first circuit layer 340 formed on the alumina layer 320, and a second circuit layer 350 formed on the first circuit layer 340. Here, the first circuit layer 340 includes a first circuit pattern 340a and a first pad 340b, and the second circuit layer 350 includes a second circuit pattern 350a corresponding to the first circuit pattern 340a and a second pad 350b corresponding to the first pad 340b. Further, the heat-radiating substrate 400 may further include a seed layer 380 formed between the copper substrate 330 and the alumina layer 320.

Descriptions of the copper substrate 330, the alumina layer 320 and the seed layer 380 in the heat-radiating substrate 400 according to this embodiment will be omitted because they are the same as those thereof in the heat-radiating substrate 300 according to the above first embodiment.

The first circuit layer 340 includes the first circuit pattern 340a and the first pad 340b, and is formed on the alumina layer 320. Here, the first circuit layer 340, in the process of manufacturing the heat-radiating substrate 400, is formed by forming the alumina layer 320 by an anodizing process and then selectively removing and patterning the aluminum substrate 310 which has been used as a base member in the anodizing process.

The second circuit layer 350 includes the second circuit pattern 350a and the second pad 350b, and is formed on the first circuit layer 340. Concretely, the second circuit pattern 350a corresponds to the first circuit pattern 340a, and the second pad 350b corresponds to the first pad 240b. Here, the second circuit layer 350 may be made of copper, but the present invention is not limited thereto.

Method of Manufacturing a Heat-Radiating Substrate

FIGS. 7 to 11 are sectional views showing a method of manufacturing a heat-radiating substrate according to a first embodiment of the present invention. Hereinafter, the method of manufacturing a heat-radiating substrate according to this embodiment will be described with reference to FIGS. 7 to 11.

First, as shown in FIG. 7, an aluminum substrate 310 is provided. Here, the aluminum substrate 310, which is used to form an alumina layer 320 using an anodizing process, is entirely or partially removed after a copper substrate 330 has been later formed on the alumina layer 320.

Subsequently, as shown in FIG. 8, the aluminum substrate 310 is anodized to form an anodized substrate 311 having alumina layers 320 formed on both sides thereof. Here, the alumina layer 320, which is an insulation layer, serves to prevent a first circuit layer 340 and a copper substrate 330 which will be formed in subsequent processes from shorting out.

A process of forming the alumina layer 320 is described in detail. That is, the alumina layers 320 are formed on both sides of the aluminum substrate 310 by connecting the aluminum substrate 310 to both electrodes of a direct current power supply and immersing the aluminum substrate 310 into an acid solution (electrolyte solution). Concretely, the surface of the aluminum substrate 310 reacts with the electrolyte solution to form aluminum ions (Al³⁺) at the interface therebetween, and the current density of the surface of the aluminum substrate 310 is increased by the voltage applied to the aluminum substrate to locally generate heat, and thus a larger amount of aluminum ions are formed by the heat. As a result, a plurality of pits are formed in the surface of the aluminum substrate 310, and oxygen ions move to the pits and then react with aluminum ions, thereby forming the alumina layer 320.

Here, since the alumina layer 320 has high thermal conductivity compared to other insulating members, the aluminum substrate 310 can easily radiate heat even though the alumina layer 320 is formed over the entire surface of the aluminum substrate 310.

Subsequently, as shown in FIG. 9, a copper substrate 330 is formed on one side of the anodized substrate 311. The copper substrate is formed by sputtering or plating.

Here, a sputtering process is a process of forming a metal thin film by spraying metal particles onto a target surface. A gold, silver or copper thin film may be formed using this sputtering process.

Meanwhile, after the alumina layer 320 is formed as shown in FIG. 8, a seed layer 380 may be previously formed in order to form the copper substrate 330 using electrolytic plating. In this case, the seed layer 380, which is a thin metal layer formed on the alumina layer using sputtering or electroless plating, has a thickness suitable for electrolytic plating, and serves as an incoming line for forming the copper substrate 330 using electrolytic plating.

Subsequently, as shown in FIG. 10, the anodized substrate 311 excluding the alumina layer 320 which is in contact with the copper substrate 330 is removed. Concretely, the anodized substrate 311 one side of which is provided with the copper substrate 330 is immersed into an etching solution, and the composition of the etching solution and the etching time are adjusted, thus removing the aluminum substrate 310 and the alumina layer 320 formed on the other side of the aluminum substrate 310. In conclusion, the aluminum substrate 310, which was used to form the alumina layers 320, is entirely removed, and the copper substrate 330 is provided on one side thereof with the alumina layer 320.

Subsequently, as shown in FIG. 11, a first circuit layer 340 is formed on the exposed surface of the alumina layer 320 adjacent to the copper substrate 330. The first circuit layer 340 includes a first circuit pattern 340a and a first pad 340b.

Concretely, a dry film is applied onto the alumina layer 320, and is then irradiated with ultraviolet (UV) with it blocked by a mask. Thereafter, when a developer is applied to the dry film, the portion of the dry film which was cured by the ultraviolet irradiation is left over, whereas the other portion of the dry film which was not cured by the ultraviolet irradiation is removed, thus forming a plating resist pattern. Then, the first circuit layer 340 is formed on the alumina layer 320 exposed by the plating resist pattern using a plating process, and then the plating resist pattern is removed.

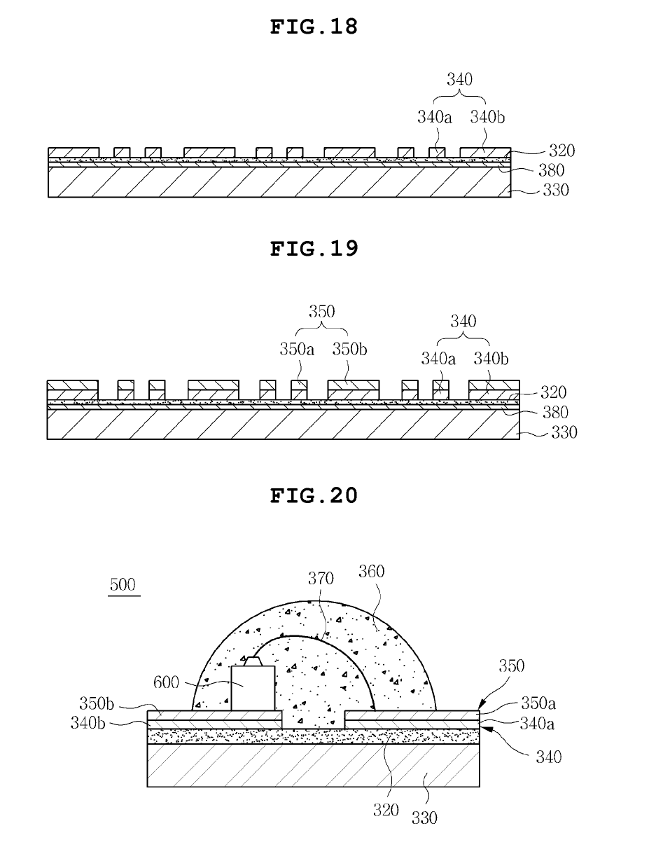

FIGS. 12 to 19 are sectional views showing a method of manufacturing a heat-radiating substrate according to a second embodiment of the present invention. Hereinafter, the method of manufacturing a heat-radiating substrate 400 according to this embodiment will be described with reference to FIGS. 12 to 19.

First, processes of manufacturing a heat-radiating substrate shown in FIGS. 12 to 14 according to this embodiment are identical with the above processes of manufacturing a heat-radiating substrate shown in FIGS. 7 to 9 according to the first embodiment.

Subsequently, as shown in FIG. 15, the alumina layer 320 formed on the other side of the aluminum substrate 310 is removed, and then the aluminum substrate 310 is partially removed to be of a predetermined thickness. Here, the term “predetermined thickness” means the thickness of a first circuit layer 340 which will be formed using the remaining aluminum substrate 310 in subsequent processes.

In this case, the anodized substrate 311, one side of which is provided with the copper substrate 330, is immersed into an etching solution, and the composition of the etching solution and the etching time are adjusted, thus partially etching the aluminum substrate 310.

Subsequently, as shown in FIG. 16, a dry film is applied onto the remaining aluminum substrate 310, and is then patterned to form an etching resist pattern 325. The method of forming the etching resist pattern is performed in the same manner as above.

Subsequently, as shown in FIGS. 17 and 18, the aluminum substrate 310 exposed by the etching resist pattern 325 is etched to selectively remove the aluminum substrate 310 (refer to FIG. 17), and then the etching resist pattern 325 is removed to form a first circuit layer 340 (refer to FIG. 18). Here, the first circuit layer 340 includes a first circuit pattern 340a and a first pad 340b.

Subsequently, as shown in FIG. 19, a second circuit layer 350 is formed on the first circuit layer 240. Here, the second circuit layer 350 includes a second circuit pattern 350a and a second pad 350b. Further, the second circuit layer 350 is configured such that the second circuit pattern 350a corresponds to the first circuit pattern 340, and the second pad 350b corresponds to the first pad 340b.

In this case, the second circuit layer 350 may be made of copper, but the present invention is not limited thereto. Meanwhile, a process of forming the second circuit layer 350 is identical with the above process of forming the first circuit layer 340 in the method of manufacturing a heat-radiating substrate 300 according to the first embodiment of the present invention.

Moreover, the heat-radiating substrate 300 or 400 according to the first or second embodiment of the present invention discharges the heat emitted from a heat-generating element to the atmosphere. Hereinafter, heat-radiating substrates, each of which is mounted with a heat-radiating element, will be described.

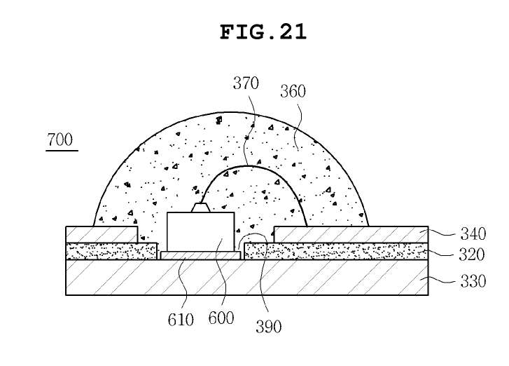

FIG. 20 is a sectional view showing a heat-radiating substrate mounted with a heat-generating element according to the second embodiment of the present invention.

In the heat-radiating element 400 according to the second embodiment of the present invention, a heat-generating element 600 may be mounted on the second pad 350b of the second circuit layer 350. When the first pad 340b is made of aluminum and the second pad 350b is made of copper, the heat-radiating substrate 400 can effectively discharge the heat emitted from the heat-generating element 600 because copper has high thermal conductivity. Further, when the first pad 340b is made of aluminum, adhesion between the first pad 340 and the heat-generating element 600 is low, so that, in order to improve the adhesion therebetween, the second pad 350b may be an adhesion layer.

Meanwhile, in the heat-radiating element 300 according to the first embodiment of the present invention, a heat-generating element 600 may be mounted on the first pad 340b of the first circuit layer 340. That is, the second circuit layer 350 shown in FIG. 20 may be selectively omitted. When the first pad 340b is made of copper, the heat-radiating substrate 300 can effectively discharge the heat emitted from the heat-generating element 600 to the atmosphere because copper has high thermal conductivity.

FIG. 21 is a sectional view showing a heat-radiating substrate, in which a heat-generating element 600 is directly mounted on a copper substrate 330, according to the first or second embodiment of the present invention.

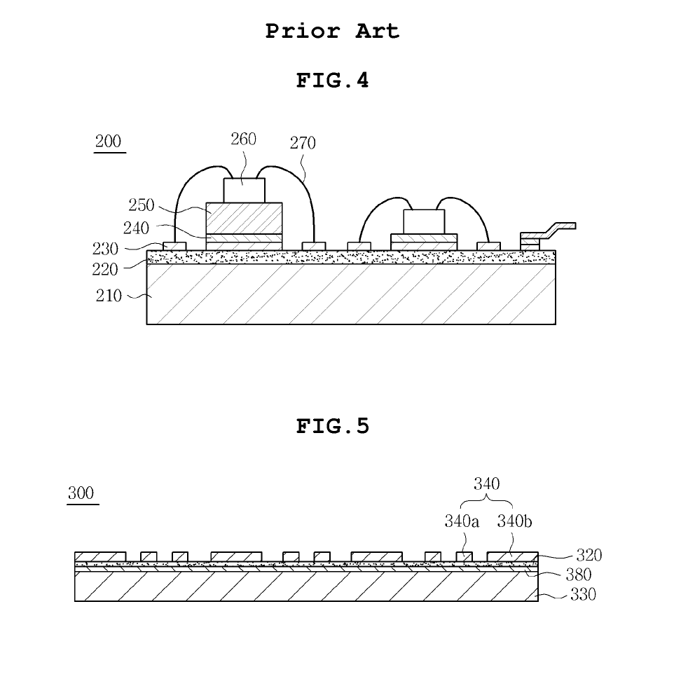

Concretely, in the heat-radiating substrate 300 or 400 according to the first or second embodiment of the present invention, an opening 390 is formed in the alumina layer 320, and a solder pad 610 adheres onto the copper substrate 330 exposed by the opening 390 formed in the alumina layer 320, and then a heat-generating element 600 is mounted on the solder pad 610. In this case, since the alumina layer 320 having thermal conductivity lower than that of copper has been removed so that the heat-generating element 600 can be directly connected to the copper substrate 330, the heat-radiating substrate 300 or 400 can more effectively discharge the heat emitted from the heat-generating element 600 to the atmosphere. Meanwhile, in the conventional heat-radiating substrate package 200 (refer to FIG. 4) in which an epoxy resin layer is used as an insulation layer, it is impossible to directly mount the heat-radiating substrate 200 with the heat-generating element 600 because the epoxy resin layer cannot be easily removed from the heat-radiating substrate 200. However, the heat-radiating substrate 300 or 400 according to the first or second embodiment of the present invention can solve the above problem, thus maximizing the heat radiation effect of a heat-radiating substrate package 700.

As described above, according to the present invention, in the heat-radiating substrate fabricated using an aluminum substrate as a base member by an anodizing process, a copper substrate having high thermal conductivity is used as a base member instead of the aluminum substrate, thus improving heat radiation characteristics.

Further, according to the heat-radiating substrate of the present invention, an alumina layer formed by an anodizing process is used instead of an epoxy resin layer generally used as an insulation layer, thus solving the problem of an insulation layer separating off at high temperature. Further, since the alumina layer formed by an anodizing process is a high-purity insulation layer, the heat radiation characteristics of the heat-radiating substrate can be further improved.

Furthermore, according to the heat-radiating substrate of the present invention, an alumina layer can be easily removed compared to an epoxy resin layer, so that a heat-generating element can be directly mounted on a copper substrate exposed by partially removing the alumina layer, thereby maximizing the heat radiation characteristics of the heat-radiating substrate.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A heat-radiating substrate, comprising:
a copper substrate;
an alumina layer formed on one side of the copper substrate; and
a first circuit layer formed on the alumina layer and including a first circuit pattern and a first pad.

2. The heat-radiating substrate according to claim 1, further comprising: a second circuit layer including a second circuit pattern corresponding to the first circuit pattern and a second pad corresponding to the first pad.

3. The heat-radiating substrate according to claim 1, wherein the first pad includes a heat-generating element mounted thereon.

4. The heat-radiating substrate according to claim 2, wherein the second pad includes a heat-generating element mounted thereon.

5. The heat-radiating substrate according to claim 1, further comprising: an opening formed in the alumina layer,
wherein a heat-generating element is mounted on the copper substrate exposed by the opening using a solder pad.

6. The heat-radiating substrate according to claim 2, further comprising: an opening formed in the alumina layer,
wherein a heat-generating element is mounted on the copper substrate exposed by the opening using a solder pad.

7. The heat-radiating substrate according to claim 1, wherein the first circuit layer is made of copper or aluminum.

8. The heat-radiating substrate according to claim 2, wherein the first circuit layer is made of aluminum, and the second circuit layer is made of copper.

9. The heat-radiating substrate according to claim 1, further comprising: a seed layer formed between the copper substrate and the alumina layer.

10. A method of manufacturing a heat-radiating substrate, comprising:
providing an anodized substrate including an aluminum substrate and an alumina layer formed on both sides of the aluminum substrate;
forming a copper substrate on one side of the anodized substrate;
removing the anodized substrate except for a portion of the alumina layer of the anodized substrate which is in contact with the copper substrate; and
forming a first circuit layer including a first circuit pattern and a first pad on the exposed surface of the alumina layer which is in contact with the copper substrate.

11. The method according to claim 10, further comprising, after the forming of the first circuit layer:
forming an opening in the alumina layer; and
mounting a heat-generating element on the copper substrate exposed through the opening using a solder pad.

12. The method according to claim 10, further comprising, after the forming of the first circuit layer: mounting a heat-generating element on the first pad.

13. The method according to claim 10, wherein the first circuit layer is made of copper.

14. The method according to claim 10, further comprising, between the providing of the anodized substrate and the forming of the copper substrate: forming a seed layer on the one side of the anodized substrate.

15. A method of manufacturing a heat-radiating substrate, comprising:
providing an anodized substrate including an aluminum substrate and an alumina layer formed on both sides of the aluminum substrate;
forming a copper substrate on one side of the anodized substrate;
removing the alumina layer formed on the side of the aluminum substrate on which the copper substrate was not formed and then partially removing the aluminum substrate to form a first circuit layer including a first circuit pattern and a first pad; and
forming a second circuit layer including a second circuit pattern corresponding to the first circuit pattern of the first circuit layer and a second pad corresponding to the first pad of the first circuit layer.

16. The method according to claim 15, further comprising, after the forming of the second circuit layer:
forming an opening in the alumina layer; and
mounting a heat-generating element on the copper substrate exposed through the opening using a solder pad.

17. The method according to claim 15, further comprising, after the forming of the second circuit layer: mounting a heat-generating element on the second pad.

18. The method according to claim 15, wherein the second circuit layer is made of copper.

19. The method according to claim 15, further comprising, between the providing of the anodized substrate and the forming of the copper substrate: forming a seed layer on the one side of the anodized substrate.
